(19) United States
(12) Patent Application Publication
(10) Pub. No.: US 2010/0270575 A1
(43) Pub. Date: Oct. 28, 2010

(54) AC LED package structure

(75) Inventors: Pei-Hsuan Lan, Banciao City (TW); Jui-Hung Chen, Taoyuan City (TW); Jen-Hua Yang, Luodong Township (TW); Yu-Bing Lan, Banciao City (TW)

Correspondence Address: BACON & THOMAS, PLLC, 625 SLATERS LANE, FOURTH FLOOR, ALEXANDRIA, VA, 22314-1176, US

(73) Assignee: Forward Electronics Co., Ltd., Taipei City (TW)

(21) Appl. No.: 12/588,326

(22) Filed: Oct. 13, 2009

(30) Foreign Application Priority Data
Apr. 27, 2009 (TW) 098207040

(51) Int. Cl. H01L 33/00

(52) U.S. Cl. 257/99; 257/E33.056

(57) ABSTRACT

An AC LED package structure includes a heat-sink slug, an AC LED module, a positive-electrode frame, a negative-electrode frame, and an insulation submount. The AC LED module is electrically connected with the positive-electrode frame and the negative-electrode frame, respectively. The insulation submount is interposed between the AC LED module and the heat-sink slug. The insulation submount is characterized by having a voltage-resistance value greater than 1000 volts. Therefore, it is possible to prevent the AC LED chip of an AC LED device from being broken through by high voltage, causing an electric shock if a human body touches the AC LED device. And moreover, the AC LED device can satisfy the requirements of a certified safety specification.

### BACKGROUND OF THE INVENTION

1. Field of the Invention

The present invention relates to an alternate current light emitting diode (AC LED), and more particularly, to an AC LED package structure with a characteristic of high voltage resistance.

2. Description of Related Art

Referring to FIG. 1, a schematic view illustrating a conventional AC LED package structure, the AC LED package structure comprises a heat-sink slug 1, an LED chip 2, a positive-electrode frame 4, and a negative-electrode frame 5, wherein two wires 3 are led out from the LED chip 2 for connecting with the positive-electrode frame 4 and the negative-electrode frame 5, respectively. The positive-electrode frame 4 and the negative-electrode frame 5 are in connection with an electric power source (not shown) for energizing and lighting an LED device.

Since an AC LED device, when functioned, for its LED chip, is in a direct contact with an alternate current voltage supplied from a public power station, a potential problem might be occurred in contrast with a previous direct current (DC) LED device. Namely, the AC LED chip may possibly be broken through by high voltage, causing an electric shock if a human body touches the AC LED device.

For a UL high-voltage resistance safety specification, the formula resides in (1000+2 U) volts, wherein “U” refers to the working voltage of an AC electric device. Suppose the AC electric device requires an input voltage of 120 Vrms, the device needs to resist a high voltage of 1.24 kv. For an ordinary DC LED package, there is no need to consider such an issue of high voltage. This is because the voltage of a DC power supply, being converted from an AC power source through an extra controlling circuit, has been lowered down to, for example, 3.5 volts. Currently, packaging an AC LED almost follows the measure adopted for packaging a DC LED. As such, to solve the problem, as mentioned above, an improved AC LED package structure is urgently required so as to satisfy relevant safety specifications and to facilitate sale of relevant products.

### SUMMARY OF THE INVENTION

An object of the present invention is to provide an AC LED package structure, comprising a heat-sink slug, an AC LED module, a positive-electrode frame, a negative-electrode frame, and an insulation submount. The AC LED module is electrically connected with the positive-electrode frame and the negative-electrode frame, respectively. The insulation submount is interposed between the AC LED module and the heat-sink slug. The insulation submount has a voltage-resistance value greater than 1000 volts.

By way of the improved AC LED package structure, according to the present invention, the property of high-voltage resistance for AC LED products can be enhanced so as to satisfy the current safety specifications, such as UL, CE, TUV, FCC, CSA, PSE, and BSMI, and to prevent LEDs from being broken through and damaged, and human bodies from being hurt.

The insulation submount may have a thermal conductivity greater than 100 W/m·K, and may be, for instance, of a silicon insulation submount, or more preferably of diamond insulation submount.

According to the present invention, the AC LED module may be a single AC LED chip; or may consist of a plurality of AC LED chips connected in series or in parallel with one another; or of a plurality of DC LED chips connected in series or in parallel with one another; or a plurality of AC and DC LED chips connected mixedly in series or in parallel with one another. The insulation submount may be of single insulation submount; or may include a plurality of submount sections separated from one another and corresponding to the plural AC LED chips.

In the present invention, the insulation submount of the AC LED module may have a thickness greater than (or including) 100 microns. The heat-sink slug may be of copper heat-sink slug, or a heat-sink slug made of a material with a desirable thermal conductivity.

Other objects, advantages, and novel features of the present invention will become more apparent from the following detailed description when taken in conjunction with the accompanying drawings.

### BRIEF DESCRIPTION OF THE DRAWINGS

FIG. 1 is a schematic view illustrating a conventional AC LED package structure; and

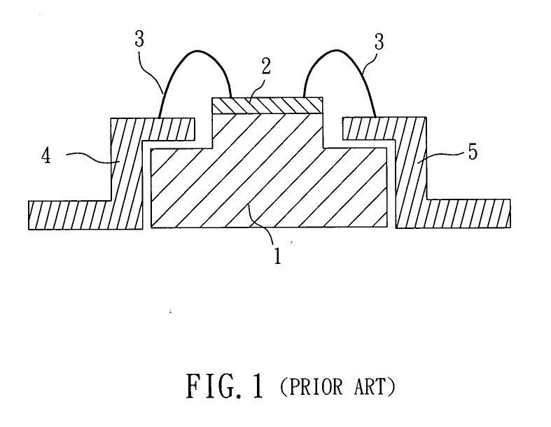

FIG. 2 is a schematic view illustrating an AC LED package structure according to the present invention.

### DETAILED DESCRIPTION OF THE PREFERRED EMBODIMENTS

The purpose of the present invention is to make greater a distance between an AC LED chip and its supporting base (or a “heat-sink slug”) so as to avoid danger to humans when a high-voltage current is conducted and flows between wires and the AC LED chip resulting in an electric arc conduction to the supporting base.

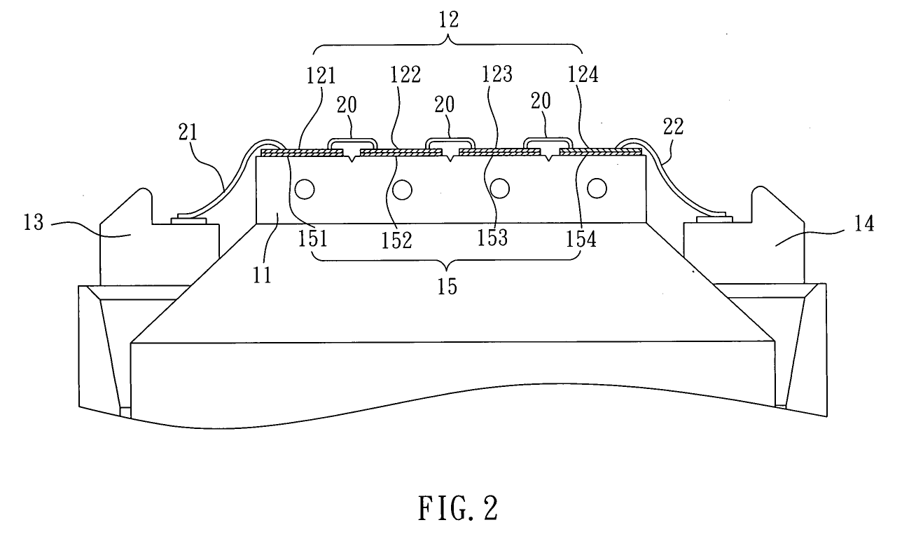

Referring to FIG. 2, a schematic view illustrating an AC LED package structure according to the present invention, the AC LED package structure comprises a heat-sink slug 11, an AC LED module 12, a positive-electrode frame 13, a negative-electrode frame 14, and an insulation submount 15. In the present invention, the AC LED module 12 consists of a plurality of AC LED chips 121 to 124 connected in series with one another. The insulation submount 15 includes a plurality of submount sections 151 to 154 corresponding to the AC LED chips 121 to 124.

The plural submount sections 151 to 154 are formed on the heat-sink slug 11 and support, correspondingly, the AC LED chips 121 to 124. The AC LED chips 121 to 124 are electrically connected with one another through the wires 20, wherein the AC LED chips 121,124 located at utmost sides from each other are electrically connected with the positive-electrode frame 13 and the negative-electrode frame 14, through wires 21 and 22 respectively.

It is noted, particularly, that the insulation submount 15 has a voltage-resistance value greater than 1000 volts, and if heat transfer capability of the heat-sink slug 11 is taken into account (normally the heat-sink slug 11 falls in a metallic material, such as a copper, with a thermal conductivity of 380 W/m·K), choices may preferably be the materials having a characteristic of better heat transfer capability, such as greater than 100 W/m·K. For instance, silicon has a thermal conductivity of about 120 W/m·K ; or preferably diamond may be the choicest. In the present embodiment, the insulation submount 15 has a thickness greater than 100 microns.

In view of the issue of high-voltage resistance, according to the present invention, the solution may, on the other hand, reside in that the substrate of the AC LED chip (normally a sapphire substrate) may increase its thickness to greater than (or including) 100 microns, in contrast to 100 to 150 microns for a conventional art. This will prevent, effectively, an accident caused by conduction of electric arc. It is understood, therefore, that in a preferable mode of embodiment, in addition to adopting a package structure on which an extra insulation submount is formed, the chip substrate may increase its thickness so as to assure avoiding a risk of electric leakage.

Although the present invention has been explained in relation to its preferred embodiments, it is to be understood that many other possible modifications and variations can be made without departing from the scope of the invention as hereinafter claimed.

What is claimed is:

1. An AC LED package structure, comprising a heat-sink slug, an AC LED module, a positive-electrode frame, and a negative-electrode frame, wherein the AC LED module is electrically connected with the positive-electrode frame and the negative-electrode frame, respectively;
characterized in that:
the AC LED package structure further comprises an insulation submount interposed between the AC LED module and the heat-sink slug, wherein the insulation submount has a voltage-resistance value greater than 1000 volts.

2. The AC LED package structure as claimed in claim 1, wherein the insulation submount has a thermal conductivity greater than 100 W/m·K.

3. The AC LED package structure as claimed in claim 1, wherein the insulation submount is a silicon insulation submount.

4. The AC LED package structure as claimed in claim 1, wherein the insulation submount is a diamond insulation submount.

5. The AC LED package structure as claimed in claim 1, wherein the AC LED module consists of a plurality of AC LED chips connected in series with one another.

6. The AC LED package structure as claimed in claim 5, wherein the insulation submount includes a plurality of submount sections corresponding to the plural AC LED chips.

7. The AC LED package structure as claimed in claim 1, wherein the insulation submount of the AC LED module has a thickness greater than 100 microns.

8. The AC LED package structure as claimed in claim 1, wherein the heat-sink slug is a copper heat-sink slug.
